(19) United States
(12) Patent Application Publication
(10) Pub. No.: US 2019/0288663 A1
(43) Pub. Date: Sep. 19, 2019

(54) ELECTROACOUSTIC FILTER WITH REDUCED PLATE MODES

(71) Applicant: SNAPTRACK, INC., San Diego, CA (US)

(72) Inventors: Sebastian BERTL, Hebertshause (DE); Carsten POTRATZ, Munich (DE)

(21) Appl. No.: 16/318,289

(22) PCT Filed: Jul. 28, 2017
(86) PCT No.: PCT/US2017/044417

§ 371 Date: Jan. 16, 2019

(30) Foreign Application Priority Data
Jul. 29, 2016 (DE) 10 2016 114 071.6

(51) Int. Cl. H03H 9/02; H03H 9/205; H03H 9/52; H03H 9/70; H03H 3/02

(52) U.S. Cl. CPC H03H 9/02834; H03H 9/205; H03H 3/02; H03H 9/70; H03H 9/52

(57) ABSTRACT

A filter with reduced plate modes is specified. Thereto, the filter has a transducer system (WS) with two or more electroacoustic split transducers (TW) connected in parallel that replace a conventional transducer (W). The static capacity of the transducer system corresponds to the sum of the static capacities of the split transducers. Each split transducer has a lower electroacoustic coupling of a desired mode than the transducer system. The transducer system has an electroacoustic coupling of a plate mode corresponding to the electroacoustic coupling of the plate mode of a split transducer.

### CROSS-REFERENCE TO RELATED APPLICATIONS

This application claims the benefit of German Patent Application Serial No. 102016114071.6, filed Jul. 29, 2016, which is herein incorporated by reference in its entirety.

### DESCRIPTION

The invention pertains to electroacoustic filters with reduced perturbances caused by plate modes, duplexer with such filters and procedures for creation of such optimized filters.

Electroacoustic filters are well suited for use as HF filters in modern communication equipment and have a piezoelectric material and electrodes connected to the piezoelectric material. Such filters include resonators by which, based on the piezoelectric effect, upon application of a HF signal on the electrodes, this is converted between HF signals and acoustic waves. Thus, acoustic waves are propagated in the piezoelectric material or on its surface.

The spatial distances between the electrode structures and the wave velocity are essentially determining the operation frequency of the transducer. The temperature variations are problematic, as they can modify the parameters determining the operation frequency (e.g. distances, wave velocity). For example, if the resonators in the filter are interconnected to band-pass filters, a temperature change would lead to a shift of the center frequency of the pass-band. As the specifications impose strict requirements on the performance of a filter, temperature changes can easily lead to not meeting the specifications.

A possibility to compensate a frequency drift caused by temperature consists in the use of so-called temperature-compensation layers, e.g. a silicon dioxide layer on the surface of SAW transducers (SAW=Surface Acoustic Wave).

Such temperature compensation layers modify however usually the acoustics of the transducer, so that additional and undesired electro-acoustic perturbations, e.g. plate modes can be propagated in the transducer system and compliance with the specifications becomes also difficult. Plate modes are acoustic modes that propagate along the propagation direction of the desired acoustic modes and usually have frequencies above the frequencies of the desired modes.

By variations of the thickness of the temperature compensation layer, the frequencies of the plate modes can be shifted to less critical ranges. However, the range of the less critical frequencies is reduced with the increase of additional functions of a piece of communication equipment and a deviation from the optimal layer thickness means a decrease of temperature compensation.

The frequencies of the plate modes can also be shifted by local variations, e.g. of the distance between the fingers of the electrode fingers on SAW resonators.

A degradation of the bandwidth accompanying such pitch scaling is also problematic.

The use of band suppressors for inhibiting unwanted frequency components is known e.g. from the U.S. Pat. No. 8,125,300.

Therefore, there is a requirement for temperature-compensated electroacoustic HF filters in which the perturbations by plate modes are reduced by maintaining the remaining electroacoustic chat of the filters. Such filters are necessary when a piece of communication equipment has to operate several bands, e.g. for LTE Carrier Aggregation, or the band gap between the sending and receiving bands is relatively large.

For corresponding electroacoustic filters and procedures for manufacturing of electroacoustic filters have to be taken from independent claims. Dependent claims specify advantageous embodiments.

An electroacoustic filter with reduced stimulation strength of plate modes includes a transducer system with two or more partial electroacoustic transducers. In the transducer system a desired mode is able to propagate. The static capacities of the transducer system correspond to the sum of the static capacities of the split transducers. Each split transducer has a lower electroacoustic coupling of the desired mode than the transducer system. The transducer system has an electroacoustic coupling of a plate mode corresponding to the electroacoustic coupling of the plate mode of a split transducer. The electroacoustic split transducers are connected preferably in parallel.

The following surprising relation was identified: Upon separating an electroacoustic transducer in split transducers, so that the number of stimulating electrode structures (e.g. electrode fingers in case of SAW transducers) of a split transducer is reduced compared to the original transducer, the stimulation strength and the strength of the electroacoustic coupling are also reduced. Concomitantly, the stimulation maximum is propagated in proportion to the degree of separation. Thus, the coupling of the desired modes and the coupling of the plate modes are reduced accordingly. In case the electroacoustic split transducers are connected electrically just so as the sum of the stimulating electrode structures corresponds to the number of the electrode structures of the original converter, and the transducer system has the same static capacity as the original transducer, the electroacoustic coupling of the desired modes is restored. Concomitantly, the electroacoustic coupling of the undesired plate modes remains at a significantly lower level of a single split transducer. At virtually unchanged desired electroacoustic chat, the stimulation strength of the undesired plate modes is thus significantly reduced.

It is possible to have a number of electroacoustic split transducers of n=2, 3, 4, 5, 6, 7, 8 or more. Here, n gives the degree of separation of the transducer system and determines the factor by which the coupling of undesired plate modes is reduced at unchanged desired acoustic chat.

It is possible and preferred to do the separation of the transducers into split transducers in a uniform mode, i.e. the split transducers have the same area, the same aperture and the same finger length.

It is possible to have SAW transducers or GBAW transducers (GBAW=Guided Bulk Acoustic Wave) as split transducers.

It is possible for the transducer system to replace a single transducer with the transducer system having the same static capacity as the replaced transducer. In addition, the transducer system replacing the single transducer has the same electroacoustic coupling of the desired mode as the single transducer. The transducer system replaces however a single transducer with the n-times the electroacoustic coupling of the plate mode.

It is possible that each of the electroacoustic split transducers has an equal number of electrode fingers.

It is possible that each of the electroacoustic split transducers has the same static capacity.

Besides, it is possible for the electroacoustic filter to feature an inductive element. The inductive element is connected in series or in parallel to the transducer system or to one of the transducer systems in case there are several transducer systems.

The interconnection of an inductive element with a transducer or a transducer system replacing the transducer can lead to an additional null point or to an additional pole point in the admittance (conductivity) of a transducer. Especially, the series connection can present on the transducer or transducer system an additional pole point. A parallel connection to the transducer or the transducer sys, respectively and inductance can present an additional null point of admittance.

An additional null point or an additional pole point provides the developer of an HF filter the possibility to specifically suppress frequencies in the range of the null point or the pole position. Therefore, even with the transducers which are replaced by the above-mentioned transducer systems, it is possible to render harmless residual disturbances caused by plate modes by the targeted placement of a null point or of a pole position.

The electroacoustic filter may contain basic elements of a so-called ladder-type filter circuit. A ladder-type filter circuit has serial resonators, interconnected in a signal path, and parallel resonators interconnecting to the ground various circuit nodes in the signal path to the ground. An element of a ladder-type circuit has a series resonator and a parallel resonator. By series circuits of such elements, one can achieve easily band-pass filters or notch filters. Electroacoustic resonators have a resonance frequency at which the admittance is very high, and an anti-resonance frequency with lower admittance. At band-pass filters, the serial and parallel resonators are matched so that basically, the anti-resonance frequency of the parallel resonator matches the resonance frequency of the serial resonator. In case of notch filters, basically, the anti-resonance frequency of the serial filter corresponds to the resonance frequency of the parallel resonator.

Thus, the resonance frequencies generate basically pole points of admittance, while anti-resonance frequencies generate null points of admittance.

Due to the possibility of adding extra pole points—especially to parallel resonators—and null points, respectively, especially to the transmission behavior of serial resonators, one can suppress undesired modes, significantly over or under the pass-band frequencies or the stopband.

It is thus possible to interconnect the transducer system or a remaining transducer to a signal path and to connect the inductive element in parallel to such transducer system or transducer. Alternatively or additionally, it is possible to interconnect the transducer system or a transducer to a parallel path and to connect the inductive element in series to the transducer system or transducer, respectively.

In the first case, one achieves an additional pole point with the inductive element. In the second case, one achieves with the inductive element an additional null point in the admittance.

It is also possible to connect the inductive element in parallel and create an additional null point of the admittance and/or to connect the inductive element in series to the transducer system and to obtain an additional admittance pole point.

It is possible that the transducer system be a multigate-resonator with at least one acoustic reflector between the split transducers. A multigate-resonator is thus a multiport resonator with interconnected reflectors, in order to compensate the higher need for surface in transducer systems split into split transducers.

The reflectors reduce the possible distances of the split transducer, which could cause acoustic perturbations without a reflector.

It is possible that the above electroacoustic filter be part of a duplexer, e.g. part of a sending filter or part of a receiving filter.

Besides, it was seen that not any electroacoustic transducer of a HF filter is equally detrimental regarding the stimulation of plate modes. The main disadvantage of increased surface requirement can thus be limited at electroacoustic transducers with especially high perturbation inputs. Accordingly, a procedure for obtaining an electroacoustic filter includes the following steps:
Analysis of the individual transducers regarding the electroacoustic coupling strength of a plate mode,
Replacement of the transducer with the highest electroacoustic coupling strength of the plate mode by a transducer system with at least two split transducers connected in parallel, where the electroacoustic coupling strength of the plate mode of the transducer system is limited to the electroacoustic coupling strength of the plate mode of one of the split transducer.

An alternative procedure includes the following steps:
Analysis of the individual transducers regarding the electroacoustic coupling strength of a plate mode,
Addition of a serial or parallel inductance to a transducer that does not have the highest electroacoustic coupling strength of the plate mode.

Usually, one does not attempt to suppress with an inductance the plate mode of the transducer. The reason is that the admittance of a transducer is subjected to a strong change in the range of the plate mode and the desired behavior (pole/null point) is not stable. Therefore, one prefers to fit another transducer with an inductance connected in parallel or in series and to select the inductance so that the pole point (in case of a transducer with parallel circuit) or the null point (in case of a transducer with serial circuit) is placed so that the plate mode of the critical transducer in the filter transferor function appears to be significantly reduced.

The possibilities of reducing perturbations caused by plate modes can be used in combination.

The above filters can have transducers with temperature compensation layers, e.g. of silicone dioxide. The perturbations caused by the additional temperature compensation layer are avoided or, at least sufficiently diminished. Typical application fields of such filters are mobile radio filters, Wireless-LAN applications and GPS receivers.

In SAW transducers or in GBAW transducers, there are periodically connected, intertwined electrode fingers applied to a piezoelectric material and alternatingly interconnected to two bus bars.

The undesired plate modes have frequency components significantly distinguished from the center frequency of the pass-bands or stop-bands of the filters. At frequencies significantly outside this frequency range of the filters, an electroacoustic transducer acts as a capacitive element. The transducer, as capacitive element, interconnected to an inductance, forms a serial oscillating circuit or a parallel oscillating circuit, respectively. Its resonance frequency or anti-resonance frequency, respectively, results in the creation of additional mull points or pole pointe, respectively.

The surprising improvements of the admittance of HF filters were confirmed in good concordance across simulations and physically performed tests setups.

The electroacoustic filter and its operation mode and electrical chat as well as execution examples of the invention are further explained based on the schematic figures.

Shown are:

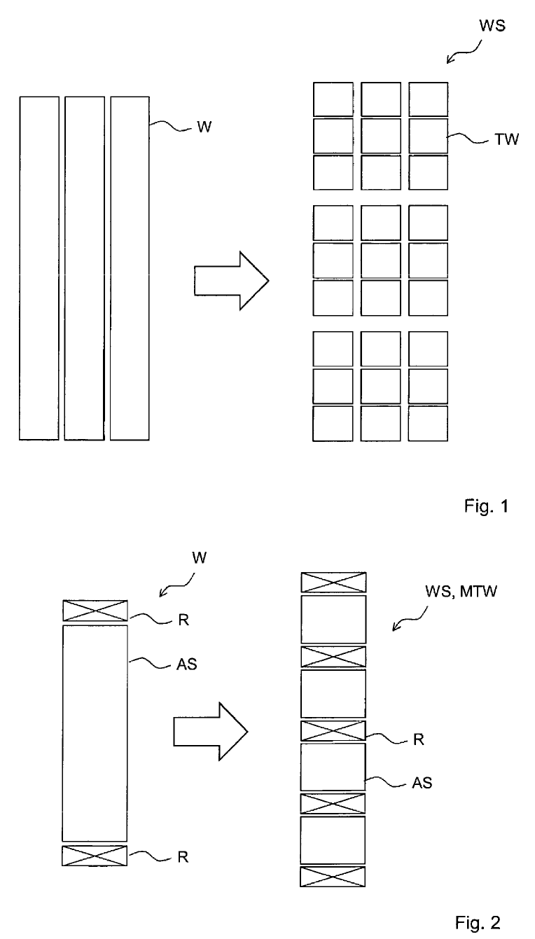

FIG. 1: a separation of a transducer into a transducer system with split transducers,

FIG. 2: the separation of a transducer into a multigate resonator,

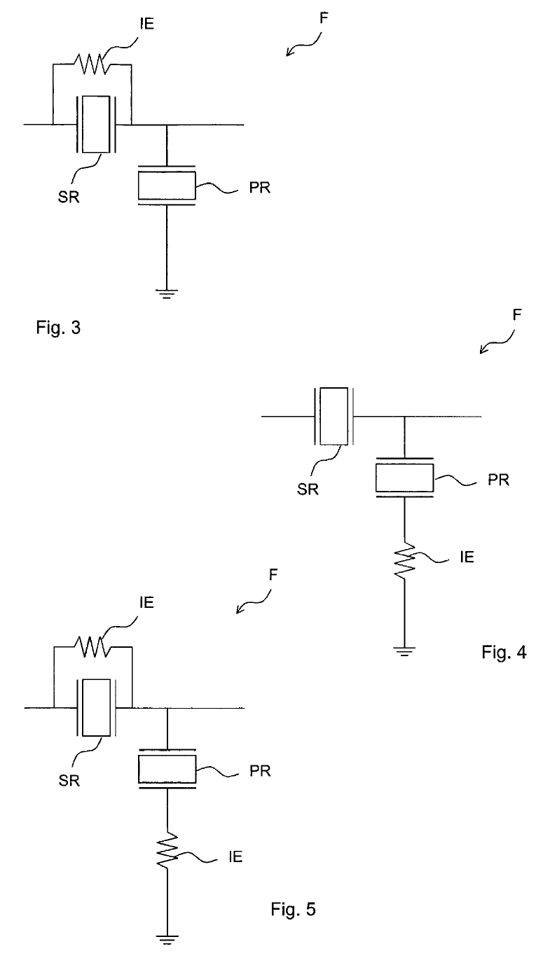

FIG. 3: the parallel circuit of an inductive element with a serial resonator,

FIG. 4: the parallel circuit of an inductive element with a parallel resonator,

FIG. 5: the parallel circuit of an inductive element with a serial resonator at concomitant serial circuit of a parallel resonator with an inductive element in a parallel path,

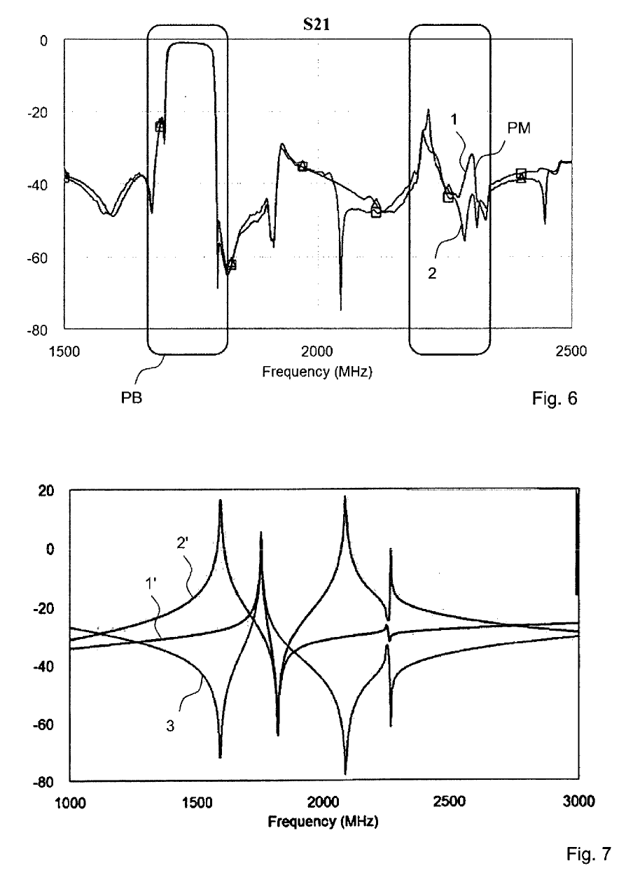

FIG. 6: comparison of an improved electroacoustic filter having a reduced stimulation strength of the plate modes to a conventional filter,

FIG. 7: comparison of a conventional resonator to a resonator interconnected in parallel or in series, respectively, to a inductive element,

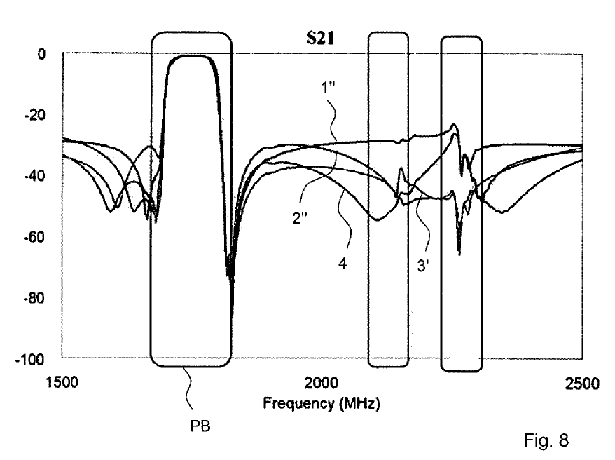

FIG. 8: comparison of an improved electroacoustic filter having one or two inductive elements to a conventional electroacoustic filter.

FIG. 1 shows a layout where a transducer with is split in a transducer system WS with split transducers TW. The transducer with itself is part of a filter where three transducers with are adjoining. Correspondingly, the filter has three transducer systems WS each with nine split transducers. The separation degree of the transducer into split transducers is thus n=9. Thus, the stimulation strength of a plate mode is reduced basically to one ninth of the stimulation strength of the original transducer—with other electroacoustic chat remaining equal.

FIG. 2 shows an example of a split transducer as multiport-resonator. The original transducer was split into four split transducers.

A conventional acoustic element consists of two reflectors and the transducer itself. The reflectors are limiting the acoustic wave to the transducer area. Two conventional transducers have thus four transducers in total.

In case a transducer is split as per above, n split transducers result and 2n reflectors. Thus, one can replace two adjoining reflectors by a single one, saving thus place on the expensive piezoelectric monocrystal. Between two split transducers only one reflector is thus placed. In order to reduce the number of reflectors and thus save place, all split transducers can be placed in a row. In case of split transducers, there are thus necessary only n+1 reflectors, instead of 2n.

FIG. 3 shows an element of a ladder-type filter circuit of a HF filter F, to which a serial resonator SR is interconnected in the signal path. A parallel resonator PR is placed in a parallel path, which interconnects the signal path to ground. Depending on how the resonance frequency or the anti-resonance frequency, respectively, of the serial resonator SR and parallel resonator PR are matched one to another, this forms the element of a band-pass filter or of a notch filter. An inductive element IE, an inductance, e.g. a coil made as metallization in a multilayer substrate or a SMD coil is interconnected in parallel to the serial resonator SR and creates an additional null point of the admittance.

FIG. 4 shows the possibility of interconnecting an inductive element IE in series to the parallel resonator between the signal path and ground in order to achieve an additional pole point of the admittance.

FIG. 5 shows the possibility to interconnect both an inductive element IE parallel to an serial resonator SR and an inductive element IE in series to a parallel resonator PR, in order to achieve both an additional pole point and an additional null point of admittance.

FIG. 6 shows the frequency-dependent transmission (matrix element S₂₁) in a logarithmic representation. Significantly above the pass-band PB of the filter, curve 1 of a conventional band-pass filter has a range of increased transmission, caused by a plate mode PM. In contrast to it, curve 2 presents the transmission of an analogue electroacoustic filter with a transducer system replacing a critical transducer. In the plate mode range, the transmission is significantly reduced, so that the specifications for frequency ranges are significantly easier to maintain outside the pass-band.

The admittance course in the pass-band range is virtually not changed when replacing a transducer by the transducer system.

FIG. 7 shows the frequency-dependent admittance of a conventional resonator 1′. Curve 2′ shows the admittance of the same transducer to which an inductance is connected in series. Curve 3 shows the admittance of a parallel circuit of the resonator of the curve 1′ and an inductance. The admittance of the series circuit of resonator and inductivity has an additional pole point. The admittance of the parallel circuit of resonator and inductance has an additional pole point.

FIG. 8 shows the effect of additional inductance elements in band-pass filters. While the die admittances of various filter configurations in the pass-band PB range are quasi-unchanged and curve 1″ shows the admittance of a filter without additional inductances, curve 2″ shows the admittance of a filter where an inductance is interconnected in parallel to the first serial transducer looking to the signal direction. The additional null point was placed by selection of the inductance value so that it has about 2150 MHz in the plate mode range of the parallel resonators. Curve 3″ shows the admittance of a filter where an inductance is connected in series to a parallel transducer. The additional pole is located in the region of the plate modes of the serial transducer at about 2250 MHz. Curve 4″ shows the admittance of a filter where an inductance is connected in series to a parallel transducer and also an inductance is connected in parallel to a serial transducer. Correspondingly, undesired plate modes can be suppressed in parallel and serial transducers.

The electroacoustic filter, the duplexer and the procedure for creating of filters are not limited by the described chat and execution examples. Filters with additional circuit elements such as additional resonators or additional inductive and capacitive elements are also included.

### LIST OF REFERENCE SIGNS

1, 1′, 1″: frequency-depending admittance
2, 2′, 2″: frequency-depending admittance
3, 3′: frequency-depending admittance
4: frequency-depending admittance
AS: acoustic trace
F: HF filter
IE: inductive element
MTW: Multi-gate transducer, multiport-resonator
PB: Pass-band
PM: Plate mode
PR: Parallel resonator
R: Reflector
S21: Matrix element
SR: Series resonator
TW: split transducer
W: Transducer
WS: Transducer sys

1. An electroacoustic filter (F), comprising:
a plurality of transducers (W); and
an inductive element (IE) connected to a single transducer (W) of the plurality of transducers that does not have a highest electroacoustic coupling of a plate mode among the plurality of transducers.

2. The electroacoustic filter (F) according to claim 1, wherein the inductive element (IE) is connected in series to the single transducer (W).

3. The electroacoustic filter (F) according to claim 1, wherein the inductive element (IE) is connected in parallel to the single transducer (W).

4-9. (canceled)

10. A duplexer with an electroacoustic filter according to any of claims 1-3.

11. A method for creating an electroacoustic filter (F), comprising:
analyzing an electroacoustic coupling strength of a plate mode in each of a plurality of transducers (W); and
replacing a single transducer (W) of the plurality of transducers having a highest electroacoustic coupling strength of the plate mode with a transducer system (WS) comprising a plurality of split transducers (TW) connected in parallel, such that the electroacoustic coupling strength of the plate mode of the transducer system (WS) is limited to the electroacoustic coupling strength of the plate mode of one of the split transducers (TW).

12. A method for creating an electroacoustic filter (F), comprising:
analyzing an electroacoustic coupling strength of a plate mode in each of a plurality of transducers (W); and
adding a serial or parallel inductive element (IE) to one of the plurality of transducers that does not have a highest electroacoustic coupling strength of the plate mode.
